(19) United States
(12) Patent Application Publication
(10) Pub. No.: US 2024/0152668 A1
(43) Pub. Date: May 9, 2024

(54) METHODS AND MODELS FOR DIRECT MOLECULAR CONFORMATION GENERATION

(71) Applicant: Chengdu Anticancer Bioscience, LTD., Chengdu (CN)

(72) Inventors: Hongyang Yu, Sydney (AU); Hongjiang Yu, Sydney (AU)

(21) Appl. No.: 18/386,435

(22) Filed: Nov. 2, 2023

Related U.S. Application Data
(60) Provisional application No. 63/422,325, filed on Nov. 3, 2022.

(51) Int. Cl. G06F 30/25

(52) U.S. Cl. CPC G06F 30/25

(57) ABSTRACT

Disclosed herein is a method of generating a 3D conformation of a molecule used in in-silico drug discovery. The method includes obtaining a 2D graph of the molecule. A first tensor including molecular graph information and a second tensor including graph, coordinate and distance information of atoms of the molecule are generated. A first set of feature vectors corresponding to the first tensor and a second set of feature vectors corresponding to the second tensor are further generated. The first set of feature vectors are fed to a first encoder of a generative model to generate a first output. The second set of feature vectors are fed to a second encoder of the generative model to generate a second output. The first output and the second output are combined to form an input in a decoder of the generative model to generate the 3D conformation of the molecule.

### CROSS-REFERENCE TO RELATED APPLICATIONS

The present application claims the benefit of and priority to U.S. Provisional Application Ser. No. 63/422,325, entitled “METHODS AND MODELS FOR DIRECT MOLECULAR CONFORMATION GENERATION,” filed on Nov. 3, 2022, which is hereby incorporated by reference in its entirety.

### BACKGROUND OF THE INVENTION

Generating valid three-dimensional (3D) molecule structures is valuable for downstream tasks in in-silico drug discovery, such as molecular property prediction and estimating binding affinity to a molecular target. A stable 3D structure of a molecule is also known as its conformation and is specified by the 3D Cartesian coordinates of its atoms. Traditional molecular dynamics or statistical mechanic-driven Monte Carlo methods are computationally expensive, making them not viable for screening modern artificial drug libraries which can contain billions of drug candidates. Deep learning-based generative methods have become an attractive alternative, but face many challenges such as lack of accuracy and requiring too many sampling steps to obtain satisfactory performance.

### SUMMARY

Methods disclosed herein involve generating 3D molecular conformations directly from two-dimensional (2D) molecular graphs in a single sampling step. Deep learning (DL)-based generative methods for generating 3D conformations of molecules from 2D molecular graphs have been an attractive tool in recent years. DL-based generative methods can be broadly classified into three categories: distance-based, reconstruction-based, and direct methods. The main goal of distance-based methods is to learn a probability distribution over inter-atomic distances. During inference, distance matrices are sampled from the learned distribution and converted to valid 3D conformations through post-processing algorithms A major advantage of modeling distance geometry is its roto-translation invariance. As a result, the likelihood-based objective function is also roto-translation invariant, leading to stable training and good generalization capability. A common practice adopted in the above distance-based methods is introducing virtual bonds between 2^{nd} and 3^{rd} neighboring atoms. Distance estimation is also required for these virtual bonds. These additional distances fix angles and dihedral angles between atoms which are crucial for generating valid conformations. However, they are not adequate to capture the interaction between atoms that are much farther apart in a long-sequence molecule. Another weakness of the distance-based method is the error accumulation problem. Random noise in the predicted distance can be exaggerated by a Euclidean Distance Geometry algorithm, leading to the generation of inaccurate conformations.

Reconstruction-based methods attempt to address this weakness by directly modeling the distribution of 3D coordinates. The main idea is to reconstruct valid conformations from either distorted or randomly sampled coordinates. Among the existing reconstruction-based methods, the process of transforming corrupted coordinates to stable conformations varies. Some adopt a reverse diffusion process for reconstruction, while others treat conformation generation as an optimization problem where random conformations generated by a model are tuned to match their ground truth under supervision. Despite the promising performance, these reconstruction-based methods require the design of task-specific and complicated coordinate transformation methods. This is to ensure the transformation is roto-transition or SE(3)-equivariant (i.e., a relevant symmetry between input and output for a Euclidean group of translations and rotations in 3D). To achieve this, one method employs a specialized SE(3)-equivariant Markov transition kernel. Another different method accomplishes the same by combining a task-specific adaption of the transformer with another specialized equivariant graph neural network. Furthermore, the former method requires numerous diffusing steps for each conformation generation to attain satisfactory performance. This requirement can become a significant performance bottleneck if this model is applied to high throughput virtual screening of a large number of molecules.

Accordingly, it would be desirable to develop a generative model that can produce a valid conformation directly from a 2D molecular graph in a single sampling step, without involving distance geometry or coordinate transformation. Some previous efforts have attempted to achieve this goal. Regrettably, the performance of these efforts is significantly worse than their distance-based counterparts. The main reason can be attributed to the use of an inferior graph neural network for information aggregation and direct coordinate generation without iterative refinement. Following the same framework, additional efforts aim to improve generative performance by adopting a more sophisticated graph neural network, featuring iterative conformation refinement and a loss function taking into account the symmetry permutation of atoms. While these efforts achieve competitive results as compared to other distance-based and reconstruction-based methods, acquiring permutation invariant loss function requires iterating through all permutations of a molecular graph, which can become computationally expensive for long-sequence molecules.

From the above, it can be seen that, regardless of their category, the aforementioned methods can be distilled to developing model architecture with ever-increasing sophistication and complexity, which is not ideal for the conformation generation of a large number of molecules.

Disclosed herein is a generative framework that generates 3D conformations directly from a 2D molecular graph in a single sampling step. The disclosed generative framework forgo building specialized generative model architectures. Instead, the generative framework is focused on intuitive and sensible input feature engineering. Briefly, the generative framework disclosed herein encodes a molecular graph using a symmetric tensor. The disclosed generative framework straightforwardly extends virtual bonds to high-order neighbors, leading to a fully connected symmetric tensor. The strength of these bonds is quantified by an additional feature channel which is inversely proportional to edge length (also referred to as “hops”) between atoms. For preliminary information aggregation, a kernel filter (e.g., a rectangular or square kernel filter) is employed to run through the tensor in a one-dimensional (1D) convolution manner. For example, with a kernel width of 3, the information from two immediate neighbors as well as all of their connected neighbors can be aggregated onto the center atom in a single operation. Methods may further involve generating a token-like feature vector per atom which can be directly fed to a standard transformer encoder for further information aggregation.

The generative framework disclosed herein is considerably simpler than other existing 3D conformation generative methods. It starts with building two tensors with one having only the molecular graph information and the other also including coordinate and distance information. Both tensors go through the same feature engineering step and the generated feature vectors are fed through two separate transformer encoders. The outputs of these two encoders are then combined in an intuitive way to form the input for another transformer encoder for generating conformation directly. The generative framework disclosed herein has been demonstrated through extensive experiments on two benchmark datasets. With sensible feature engineering, the relatively simple model disclosed herein can perform competitively against other models with extensive sophistication and complexity, thereby improving the efficiency of 3D conformation generation in in-silico drug discovery.

Additionally disclosed herein is a neural network included in the disclosed generative model. Compared to other developed generative models that involve multiple sampling steps, the neural network included in the disclosed generative model can achieve the expected performance without necessarily going through multiple sampling steps. The neural network can be convenient to train, easy to deploy, and cheap to host. Accordingly, the generative framework disclosed herein can achieve competitive performance with much-simplified sampling and with improved ease in model training and deployment, all of which enable the rapid and efficient implementation of the generative framework disclosed herein (e.g., implementation as a service in providing 3D conformations in in-silico drug discovery).

Additionally disclosed herein includes a method of generating a 3D conformation of a molecule. The method includes obtaining a two-dimensional (2D) graph of the molecule. A first tensor including molecular graph information and a second tensor including graph, coordinate and distance information of atoms of the molecule are generated. A first set of feature vectors corresponding to the first tensor and a second set of feature vectors corresponding to the second tensor are further generated. The first set of feature vectors are fed to a first encoder of a generative model to generate a first output. The second set of feature vectors are fed to a second encoder of the generative model to generate a second output. The first output and the second output are combined to form an input in a decoder of the generative model to generate the 3D conformation of the molecule.

In various embodiments, generating the first tensor includes adding an additional dimension to an adjacency matrix including one or more atom features and/or one or more bond features corresponding to the molecule; a diagonal section of the first tensor holds the one or more atom features for the atoms of molecule; the atom features include one or more of an atom type, atom charge, or atom chirality; each of the atom type, atom charge, and atom chirality is one-hot encoded; the atom type, atom charge, and atom chirality for an atom included in the molecule are stacked to form an atom feature vector corresponding to the atom; atom feature vectors for the atoms of the molecule are placed along a diagonal of the first tensor; an off-diagonal section of the first tensor holds bond features for one or more bonds corresponding to atom pairs included in the molecule; the bond features include bond types of the one or more bonds; the bond types include virtual bonds; the first tensor represents a fully connected symmetric tensor in which virtual bonds are extended across all atoms of the molecule; high-order virtual bonds share a same virtual bond type; the bond features include bond stereochemistry types of the one or more bonds; the bond features include associated ring sizes of the one or more bonds; the bond features include normalized bond lengths of the one or more bonds; a normalized bond length is calculated as an actual edge length divided by a longest chain length; a bond feature vector for an atom pair is further constructed; constructing the bond feature vector for an atom pair includes summing the atom feature vectors of the atoms of the molecule to form a new vector; constructing the bond feature vector for an atom pair further includes stacking the new vector with one-hot encoded bond type vector, normalized bond length, and one-hot encoded ring size vector for a bond associated with the atom pair, the method further includes constructing bond feature vectors for all atom pairs included in the molecule, to form the first tensor; generating the second tensor includes adding a coordinate channel to one or more atom feature vectors and adding a Euclidean distance channel to one or more bond feature vectors; generating the first set of feature vectors includes encoding the first tensor using a one-dimensional (1D) convolution operation; generating the second set of feature vectors includes encoding the second tensor using a 1D convolution operation; using the 1D convolution operation includes adjusting a kernel height of a kernel to equal a height of the first tensor or the second tensor during the 1D convolution operation; a kernel height remains unchanged and equals a kernel size of a kernel used during the 1D convolution operation; the kernel size of a kernel before adjusting the kernel length is 3×3 kernel or 4×4 kernel; the kernel size of a kernel after adjusting the kernel length is N×3 kernel or N×4 kernel, wherein N is the length of the first tensor or the second tensor; the first encoder and the second encoder are transformer encoders; feeding the input to the decoder of the generative model to generate the 3D conformation of the molecule includes: computing, in a first multi-head attention layer of the decoder, query and key matrices based on the first output; feeding the input to the decoder of the generative model to generate the 3D conformation of the molecule includes: reparametrizing the second output to generate value matrices for a first multi-head attention layer of the decoder; the first encoder, the second encoder, and the decoder included in the generative model are arranged in a conditional variational AutoEncoder framework; the generative model includes a convolutional neural network; the convolutional neural network in the generative model is trained before being applied to generate the 3D conformation of the molecule; the convolutional neural network in the generative model is trained by using a first data set containing molecules averaging a first number of atoms; the first number is a number between 30-40, 40-50, 50-60, or a number larger than 60; the convolutional neural network in the generative model is trained by using a second data set containing molecules averaging a second number of atoms; the second number is a number between 20-30, 10-20, or a number smaller than 10; each of the first data set and the second data set includes energy and statistical weight annotated molecular conformations corresponding to a set of molecules; the set of molecules include at least 1,000 molecules or at least 10,000 molecules; the method achieves a coverage score (COV) of at least 92; and the method achieves a matching score (MAT) below 0.85.

### BRIEF DESCRIPTION OF THE DRAWINGS

These and other features, aspects, and advantages of the present invention will become better understood with regard to the following description and accompanying drawings. It is noted that wherever practicable similar or like reference numbers may be used in the figures and may indicate similar or like functionality. For example, a letter after a reference numeral, such as “third party entity 110A,” indicates that the text refers specifically to the element having that particular reference numeral. A reference numeral in the text without a following letter, such as “third party entity 110,” refers to any or all of the elements in the figures bearing that reference numeral (e.g., “third party entity 110” in the text refers to reference numerals “third party entity 110A” and/or “third party entity 110B” in the figures).

FIG. 1A depicts an overall system environment including an in-silico drug discovery system, in accordance with an embodiment.

FIG. 1B depicts a block diagram of the in-silico drug discovery system, in accordance with an embodiment.

FIG. 2 depicts example modules included in a molecule conformation generation module, in accordance with an embodiment.

FIG. 3A depicts an example tensor graph, in accordance with an embodiment.

FIG. 3B depicts an example process for kernel expansion and feature vector generation, in accordance with an embodiment.

FIG. 4A illustrates an example conditional AutoEncoder framework, in accordance with an embodiment.

FIG. 4B illustrates an example modified multi-head attention of a decoder, in accordance with an embodiment.

FIG. 5 illustrates an example method for generating a 3D molecular conformation, in accordance with an embodiment.

FIG. 6 illustrates an example computer device for generating a 3D molecular conformation, in accordance with an embodiment.

### DETAILED DESCRIPTION OF THE INVENTION

### System Overview

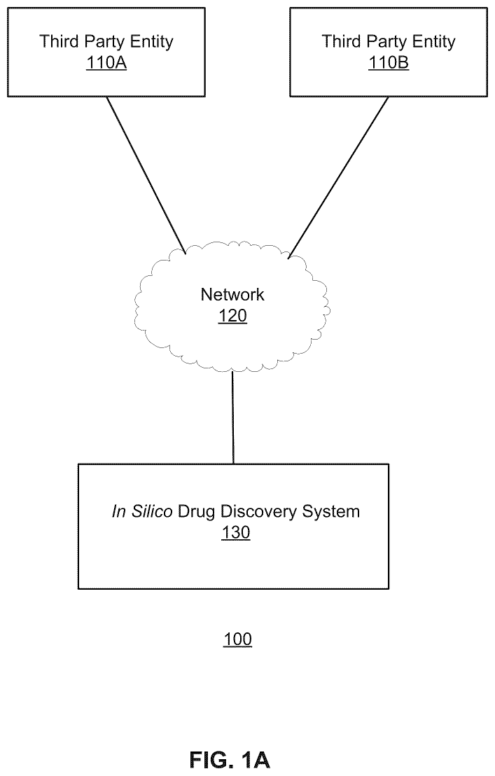

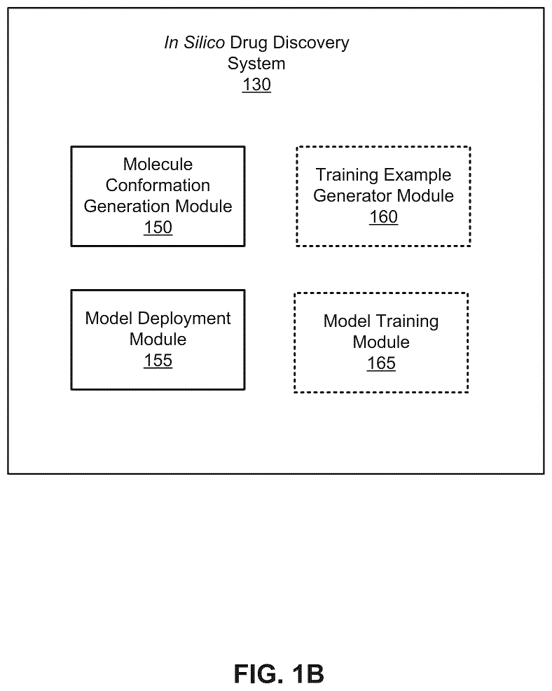

FIG. 1A depicts an overall system architecture 100 including an in-silico drug discovery system 130, in accordance with an embodiment. FIG. 1A further introduces one or more third party entities 110A and 110B in communication with one another and/or the in-silico drug discovery system through a network 120. FIG. 1A depicts one embodiment of the overall system architecture 100. In other embodiments, additional or fewer third party entities 110 in communication with the in-silico drug discovery system 130 can be included.

Generally, the in-silico drug discovery system 130 performs methods disclosed herein, such as methods for generating 3D conformations for molecules. The 3D conformations may be generated based on the 2D molecular graphs of molecules from certain sources, such as certain programs or applications for generating 2D graphs for molecules. Example 2D graphs of molecules can include molecules expressed in terms of its atoms and bonds (e.g., as nodes and/or edges). 2D graphs of molecules can be expressed as, or derived from, any of a simplified molecular-input line-entry system (SMILES) string, molecular design limited (MDL), molfile (MOL), structure data file (SDF), protein data bank (PDB), XYZ, IUPAC international chemical identifier (InChi), and MOLII format. The third party entities 110 communicate with the in-silico drug discovery system 130 for purposes associated with discovering valid small molecule compounds.

In various embodiments, the methods described herein as being performed by the in-silico drug discovery system 130 can be dispersed between the in-silico drug discovery system 130 and third party entities 110. For example, a third party entity 110A or 110B can generate training data and/or train one or more machine learning-based models included in the system architecture 100. The in-silico drug discovery system 130 can then deploy the trained machine learning models to generate 3D conformations for molecules.

Referring to the third party entities 110, in various embodiments, a third party entity 110 represents a partner entity of the in-silico drug discovery system 130. For example, the third party entity 110 can operate either upstream or downstream of the in-silico drug discovery system 130. In various embodiments, a first third party entity 110A can operate upstream of the in-silico drug discovery system 130 and a second third party entity 110B can operate downstream of the in-silico drug discovery system 130.

As one example, the third party entity 110 operates upstream of the in-silico drug discovery system 130. In such a scenario, the third party entity 110 may perform the methods of generating training data and training of machine learning-based models, as is described in further detail herein. Thus, the third party entity 110 can provide trained machine learning models to the in-silico drug discovery system 130 such that the in-silico drug discovery system 130 can deploy the trained machine learning models.

As another example, the third party entity 110 operates downstream of the in-silico drug discovery system 130. In this scenario, the in-silico drug discovery system 130 deploys trained machine learning models to generate valid 3D molecule structures for molecules. The in-silico drug discovery system 130 can provide the determined 3D molecule structures to the third party entity 110 for downstream tasks. The third party entity 110 can use the obtained 3D structural information of molecules for predicting molecular properties and estimating binding affinity to molecule targets. In various embodiments, the third party entity 110 may be an entity that identifies compounds as promising candidates for drug development.

Referring to the network 120 shown in FIG. 1A, this invention contemplates any suitable network 120 that enables connection between the in-silico drug discovery system 130 and third party entities 110. The network 120 may comprise any combination of local area and/or wide area networks, using both wired and/or wireless communication systems. In one embodiment, the network 120 uses standard communications technologies and/or protocols. For example, the network 120 includes communication links using technologies such as Ethernet, 802.11, worldwide interoperability for microwave access (WiMAX), 3G, 4G, 5G, code division multiple access (CDMA), digital subscriber line (DSL), etc. Examples of networking protocols used for communicating via the network 120 include multiprotocol label switching (MPLS), transmission control protocol/Internet protocol (TCP/IP), hypertext transport protocol (HTTP), simple mail transfer protocol (SMTP), and file transfer protocol (FTP). Data exchanged over the network 120 may be represented using any suitable format, such as hypertext markup language (HTML) or extensible markup language (XML). In some embodiments, all or some of the communication links of the network 120 may be encrypted using any suitable technique or techniques.

FIG. 1B depicts a block diagram of the in-silico drug discovery system 130, in accordance with an embodiment. FIG. 1B introduces individual modules of the in-silico drug discovery system 130 which includes, in various embodiments, a molecule conformation generation module 150, a model deployment module 155, a training example generator module 160, and a model training module 165. Generally, the molecule conformation generation module 150 is in charge of the generation of 3D structural information for molecules. For example, in the process of screening potential compounds for drug discovery, the molecule conformation generation module 150 receives 2D graph information of a large number of candidate molecules, and then generates 3D conformations for these molecules using one or more generative models included therein. The generative models include certain algorithms such as machine learning-based models that have been trained, or can be trained, for the generation of 3D structural information based on the 2D graph information of molecules. In some embodiments, the generative models are trained elsewhere, which are then provided to and deployed by in-silico drug discovery system 130. For example, the model deployment module 155 in the system 130 can deploy a trained machine learning model.

In some embodiments, the generative models can be trained by the in-silico drug discovery system 130. The training example generator module 160 generates training data for use in training these machine learning models. In particular embodiments, the training example generator module 160 generates training data for different machine learning-based generative models if more than one such model is included in the in-silico drug discovery system 130. The model training module 165 trains one or more machine learning models using the training data.

In various embodiments, the in-silico drug discovery system 130 may be differently configured than as shown in FIG. 1B. For example, there may be additional or fewer modules in the in-silico drug discovery system 130 than as shown in FIG. 1B. In various embodiments, the in-silico drug discovery system 130 need not include the training example generator module 160 or the model training module 165. In such embodiments, the steps of generating training examples (performed by the training example generator module 160) and/or training machine learning models (performed by the model training module 165) can be performed by a third party, and then the trained machine learning models can be provided to the in-silico drug discovery system 130. Further details of the particular methods performed by the molecule conformation generation module 150 are provided herein.

Molecule Conformation Generation Module

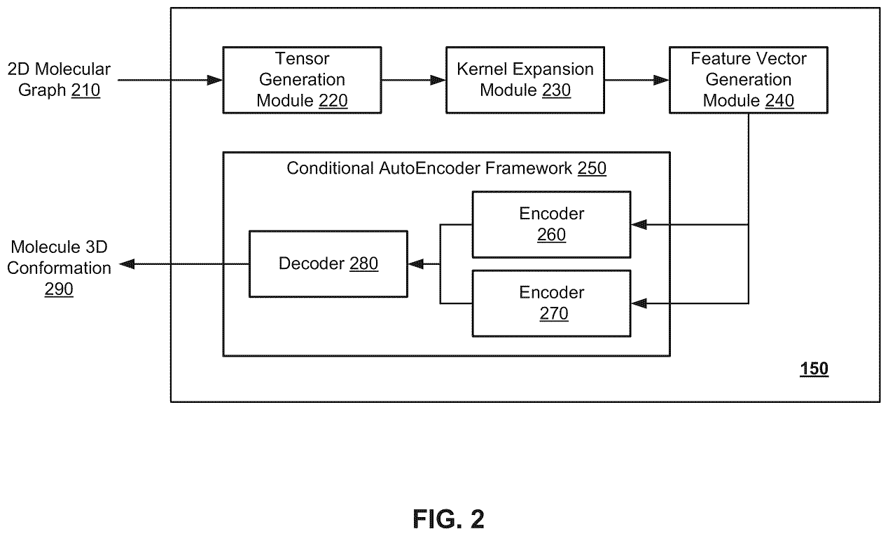

FIG. 2 depicts a block diagram of the molecule conformation generation module 150, in accordance with an embodiment. FIG. 2 introduces individual modules of the molecule conformation generation module 150, which includes, in various embodiments, a tensor generation module 220, a kernel expansion module 230, a feature vector generation module 240, and a conditional AutoEncoder framework 250. In the conditional AutoEncoder framework 250, there are two different encoders (e.g., encoder 260 and encoder 270), and one decoder 280.

The tensor generation module 220 is configured to generate one or more tensors for a molecule based on the received 2D molecular graph. For example, the tensor generation module 220 receives a 2D molecular graph 210 of a molecular from a certain source as illustrated in FIG. 2. The tensor generation module 220 then generates one or more tensors for 3D conformation generation. In various embodiments, the tensor generation module 220 generates one tensor for generating the 3D conformation. In various embodiments, the tensor generation module 220 generates two tensors for generating the 3D conformation. In various embodiments, the tensor generation module 220 generates three, four, five, six, seven, eight, nine, or ten tensors for generating the 3D conformation. For example, the tensor generation module 220 may generate one or more tensors that include atom features, bond features, and/or certain other information that can be used by the encoders and decoder in the conditional AutoEncoder framework 250 to determine the 3D conformation generation of the molecule.

According to an embodiment, the tensor generation module 220 generates one or more tensors based on the adjacency matrix of the molecule. As used herein, an adjacency matrix refers to a binary matrix whose entry indicates whether there is a connection between two atoms. To generate a tensor, the tensor generation module 220 may add an additional dimension to the adjacency matrix, e.g., add features about connected atoms and the corresponding bonds to the off-diagonal section and add atom features to the diagonal section of the matrix. The tensor generation module 220 can extract features from the tensor (e.g., using a graph neural network (GNN)). The input of GNN is generally composed of three components, including atom feature vectors, edge feature vectors, and an adjacency matrix. Atom and edge features normally pass through separate embedding steps before being fed to GNN. The adjacency matrix is then used to determine neighboring atoms for layer-wise information aggregation. Although bond features are aggregated onto atom features and vice versa, these two features are maintained separately throughout the message-passing layers. To simplify the 3D conformation generation, instead of having separate input components, the disclosed method combines bond features and atom features into a single input for a conformation generation neural network. Specifically, the tensor generation module 220 achieves this by adding an additional dimension to an adjacency matrix, making it a tensor graph (or tensor), similar to a tensor used to encode images in computer vision tasks. The as-generated tensor contains both atom features and bond features for 3D conformation generation.

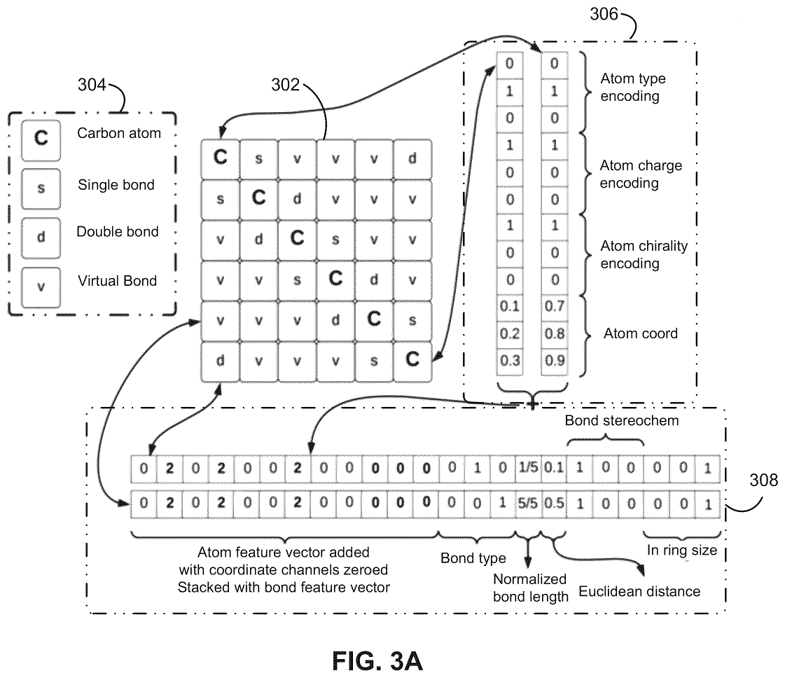

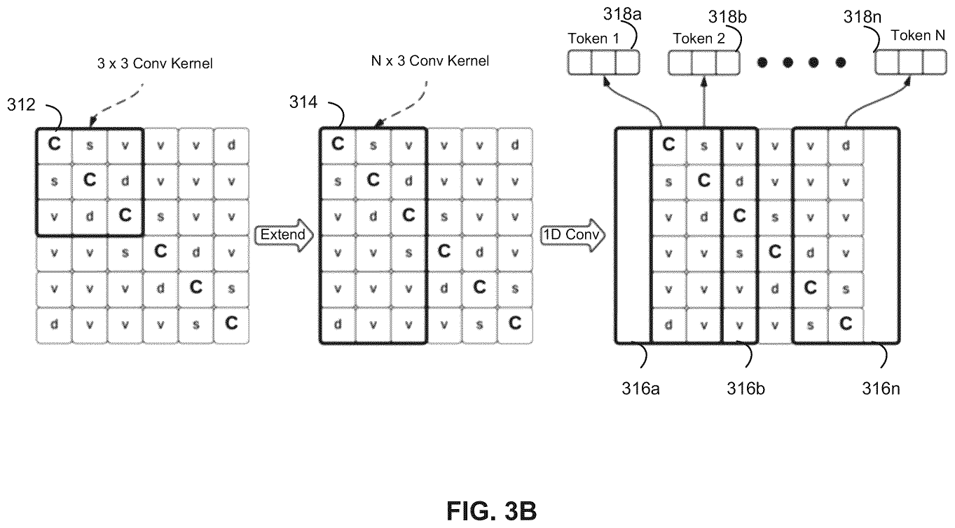

FIG. 3A illustrates an example tensor graph 302 generated for a Benzene ring by the tensor generation module 220. As illustrated, the tensor graph 302 includes a tensor-type presentation of the atoms and bonds included in the Benzene ring. The atoms of the Benzene ring are placed along the diagonal section of the tensor graph 302 while the bonds associated with the atom pairs are placed off the diagonal section. As indicated by the box 304 in FIG. 3A, the bonds include single bonds, double bonds, and virtual bonds. According to an embodiment, the virtual bonds include bonds between the 2^{nd} and 3^{rd} neighboring atoms with respect to a focal atom. In some embodiments, as is shown in FIG. 3A, the virtual bonds are extended across all atoms of the molecule (e.g., as virtual bonds “v” are shown throughout the remaining entries of tensor graph 302). As also illustrated, atom features and bond features for the atoms and bonds included in the tensor graph 302 are also extracted. For example, the box 306 in FIG. 3A includes the extracted features for the atoms included in the Benzene ring, which include atom type, atom charge, atom chirality, and atom coordinate. Each of these atom features is one-hot encoded and stacked together to form a single feature vector per atom, as indicated by the two columns of one-hot encoded values corresponding to atom features of two carbon (C) atoms in box 306. According to an embodiment, such an atom feature vector is extended to all atoms.

Similarly, the box 308 in FIG. 3A includes the extracted features for the bonds included in the Benzene ring, which include bond type, normalized bond length, bond stereochemistry, ring size, and Euclidean distance. A virtual bond is also included in the bond type. The normalized bond length is calculated as the actual edge length (1 for a direct neighbor, 2 for 2^{nd} neighbor, etc.) divided by the longest chain length. It is worth noting that all high-order virtual bonds share the same virtual bond type. These high-order virtual bonds actually differ in their normalized bond length. To construct a bond feature vector, the atom feature vectors of the related atoms (e.g., a pair of atoms corresponding to a bond) are first summed, as indicated by the left parts of the two rows of encoded bond features in box 308 in FIG. 3A. The summed atom vector is then stacked with a one-hot encoded bond type vector, normalized bond length, Euclidean distance, bond stereochemistry, and one-hot encoded ring size vector, as indicated by the two rows of one-hot encoded values in box 308 in FIG. 3A. According to an embodiment, such a bond feature vector is extended to all pairs of atoms, resulting in a fully connected tensor graph.

According to an embodiment, the tensor generation module 220 encodes the atom features and bond features according to certain predefined rules and logic. Table 1 lists some exemplary rules or logic for encoding the atoms and features. It is to be noted that the encoding methods included in Table 1 are provided for demonstration purposes and are not inclusive. In some embodiments, there are additional feature encoding rules and logics that are also possible for feature encoding, depending on the specific composition of a molecule.

TABLE 1
Encoding method for constructing a tensor graph

| Feature name | Feature value | Encoding method |
|---|---|---|
| Atom type | H, C, N, O, F, S, Cl, Br, P, I, | one-hot |
| | Na, B, Si, Se, K, Bi | |
| Atom charge | −2, −1, 0, 1, 2, 3 | one-hot |
| Atom chirality | Unspecified, Tetrahedral_CW, | one-hot |
| | Tetrahedral_CCW, Other | |
| Bond type | Single, Double, Triple, | one-hot |
| | Aromatic, Virtual | |
| Normalized bond length | — | real-valued |
| Bond stereochem | StereoNone, StereoAny, StereoZ, | one-hot |
| | StereoE, StereoCIS, StereoTrans | |
| Bond in-ring size | 3-10 | one-hot |
| Coordinate (3 channels) | — | real-valued |
| Pair wise atom distance | — | real-valued |

According to an embodiment, the tensor generation module 220 can purposely generate different tensor graphs for the same molecule. For example, for a Benzene ring, two different tensor graphs can be generated, where each tensor graph may include different information (e.g., different types of atom features and/or bond features). As described elsewhere herein, the two encoders included in the conditional AutoEncoder framework 250 are conditioned on different inputs (e.g., different tensors). Accordingly, two different tensor graphs can be purposefully generated for a same molecule for feeding the two encoders. According to an embodiment, the atom features for a first tensor graph include atom type, charge and chirality, but do not include the coordinate information. The bond features for the first tensor graph include bond type, bond stereochemistry type, associated ring size, normalized bond length, and certain virtual bonds, but do not include distance information. On the other hand, the second tensor graph includes both coordinate information and distance channels in addition to the bond features and atom features included in the first tensor. For example, an atom feature vector in the second tensor includes three additional channels incorporating the coordinates of the respective atom.

Referring back to FIG. 2, the molecule conformation generation module 150 includes a kernel expansion module 230 configured to adjust the kernel height of a kernel generated from tensor graphs in a preliminary information aggregation step for 3D conformation generation.

Having obtained the tensor graph(s), a naïve way of building a generative model includes applying a convolutional neural network directly on top of the tensor(s), and training it to predict a distribution over the distance matrix, as many other existing methods have done. Among these different methods, some further simplify the process by assuming that each Euclidean distance follows an independent Gaussian distribution, which then translates the distribution prediction problem to predicting as many means or standard deviations as there are pair-wise distances. A network architecture used by such methods includes a standard UNet, which utilizes a small size kernel (e.g., 3×3). This then causes certain drawbacks for these naïve UNet-based methods. For example, with such a small kernel size, it takes many convolution layers to achieve information aggregation between atoms that are far apart. It does not take full advantage of high-order bonds already made available in the input tensor graph. Secondly, the output size grows quadratically with the number of atoms, as compared to only linear growth in reconstruction-based or direct generation methods. The kernel expansion module 230 disclosed herein addresses the above first problem by increasing the kernel size to expand its “field of view” in preliminary information aggregation.

In various embodiments, the kernel expansion module 230 generates a kernel for use in extracting features. In various embodiments, the kernel expansion module 230 generates a square kernel. For example, a square kernel may be a 2×2 kernel, a 3×3 kernel, a 4×4 kernel, a 5×5 kernel, or a 6×6 kernel. In various embodiments, the kernel expansion module 230 generates a rectangular kernel, such as a N×2 kernel, a N×3 kernel, a N×4 kernel, a N×5 kernel, or a N×6 kernel. In particular embodiments, N represents the length of the tensor graph, such that the rectangular kernel fully extends through the length of the tensor graph.

FIG. 3B illustrates an example application scenario for increasing the kernel size in preliminary information aggregation. In the figure, box 312 illustrates a standard kernel size (e.g., 3×3) used by other existing methods, and box 314 illustrates an expanded kernel size (e.g., N×3) that is expanded by the kernel expansion module 230. As can be seen, while one dimension (e.g., width) remains unchanged, the other dimension (e.g., height or length) of the kernel is expanded to N, which equals a full height (or length) of the tensor illustrated in FIG. 3B. Since every row or column of the proposed tensor contains the complete information of the focal atom and all of its connected atoms (by both chemical and virtual bonds), by expanding the height or length to the full height or length, information from the immediate neighbors, all of their connected atoms, and all of the connecting bond features can be aggregated onto the focal atom in a single convolution operation. In contrast, achieving the same degree of information aggregation may require many layers of propagation for other graph neural network-based models. The kernel can slide in either up-down or left-right direction. However, since a tensor generated by the tensor generation module 220 is symmetric, both directions are equivalent, and thus sliding along one of the up-down or left-right direction does not affect information aggregation.

Referring back to FIG. 2, according to the illustrated embodiment, the molecule conformation generation module 150 further includes a feature vector generation module 240 configured to generate a set of feature vectors based on the expanded kernels. For example, as illustrated in FIG. 3B, based on the expanded kernel size, a first feature vector 318a for the first atom can be generated based on the first kernel 316a indicated by the first three columns in the tensor graph (including a blank column on the left of the first focal atom). Similarly, a second feature vector 318b for the second atom can be generated based on the second kernel 316b indicated by the next three columns (the first two columns are shared with the two columns of the first kernel 316a) in the tensor graph. An n^{th} feature vector 318n can be similarly generated based on the expanded kernel 316n (with the last column being blank).

According to an embodiment, the feature vector generation module 240 generates a feature vector 318 by running a rectangle kernel filter through a tensor in a 1D convolution manner. For example, the feature vector generation module 240 disclosed herein may include a 1D convolution block composed of a configurable filter. The configurable filter is configured to be N×3 in the illustrated embodiment in FIG. 3B. It is to be noted that the filter can be configured to any other proper size, depending on the specific applications.

According to an embodiment, to generate a feature vector for an atom, the feature vector generation module 240 performs a convolution operation between the tensor and the configured filter, producing as output a new feature vector for the atom. According to an embodiment, the feature vector generation module 240 generates a feature vector for each atom by moving the filter in width (which is also referred to as “horizontal stride”) by 1 atom at a time. As described earlier, since the tensor generated by the tensor generation module 220 is symmetric, the filter can be also set to 3×N. At this point, a vertical stride is then performed during the 1D convolution. In some embodiments, by striding all the way along a direction, the feature vector generation module 240 can then generate a set of feature vectors corresponding to all atoms included in a molecule. In some embodiments, if multiple tensors (e.g., two sensors for two encoders) are generated by the tensor generation module 220, the feature vector generation module 240 generates a set of feature vectors for each generated tensor.

As also illustrated in FIG. 3B, a set of feature vectors 318a-318n generated by the feature vector generation module 240 resemble the token-like feature vectors used in language modeling. The token-like feature vectors can be provided as input to a generative model with a transformer architecture. A significant advantage of using the transformer's self attention mechanism is that, similar to the expanded kernel, it enables information aggregation from all connected atoms. It also eliminates the need of maintaining separated atom and bond features at each step of feature transformation. Accordingly, according to some embodiments, the molecule conformation generation module 150 disclosed herein further includes a conditional AutoEncoder framework 250 that takes the form of a transformer architecture.

To generate 3D conformation with high confidence, the objective of a transformer architecture (e.g., transformer included in the conditional AutoEncoder framework 250) is to obtain a generative p_{θ} (R|G) that approximates the Boltzmann distribution through maximum likelihood estimation. Particularly, given a set of molecular graphs G and their respective ground-truth conformations R, the objective of a transformer architecture may maximize the following objective.

log_{pθ} (R|G)=log∫p(z)p_{θ} (R|z,G)dz (1)

A molecular graph can have multiple random and valid conformations. Assume this randomness is driven by a latent process governed by a random variable z˜p(z), where p(z) is a known distribution (e.g., a standard normal distribution). As p_{θ} (R|z, G) is often modeled by a complex function (e.g., a deep neural network), evaluation of the integral in Equation (1) is then intractable. This is undesirable in certain 3D conformation generation. Accordingly, the transformer architecture disclosed herein also resorts to establishing a tractable lower bound for Equation (1) according to the following Equation (2):

logp_{θ} (R|G)≥E_{q(z|R,G)}[logp_{θ} (R|z,G)]−D_{KL}[q_{w}(z|R,G)∥p(z)] (2)

where D_{KL} is the Kullback-Leibler divergence and q_{w} (z|R, G) is a variational approximation of the true posterior p(z|R, G). In some embodiments, assume p(z)=N (0, 1) and q_{w} (z|R, G) is a diagonal Gaussian distribution whose means and standard deviations are modeled by a transformer encoder. The input of this transformer encoder is the aforementioned tensor containing both the coordinate and distance information, which can be also referred to GDR tensor. On the other hand, p_{θ} (R|z, G) is further decomposed into two parts: a decoder p_{θ2} (R|z, σ_{θ1} (G)) for predicting conformation directly and another encoder σ_{θ1} (G). The input tensor for σ_{θ1} (G) is absent of coordinate and distance information, and is therefore denoted the G tensor. In the disclosed conditional AutoEncoder framework 250, both encoder 260 and encoder 270 share the same standard transformer encoder structure. The Query (Q), Key (K) matrices for the first multi-head attention layer are computed based on the output vectors of σ_{θ1} (G), and the Value (V) matrices come directly from the reparameterization of the output of q_{w}(z|R, G), as z=μ+Σ_{w}ϵ, where μ_{w} and Σ_{w} ϵ are the predicted mean and standard deviation respectively. ϵ is sampled from N (0, 1). A complete picture of how the two encoders and the decoder are arranged in a conditional variational AutoEncoder framework in further illustrated below.

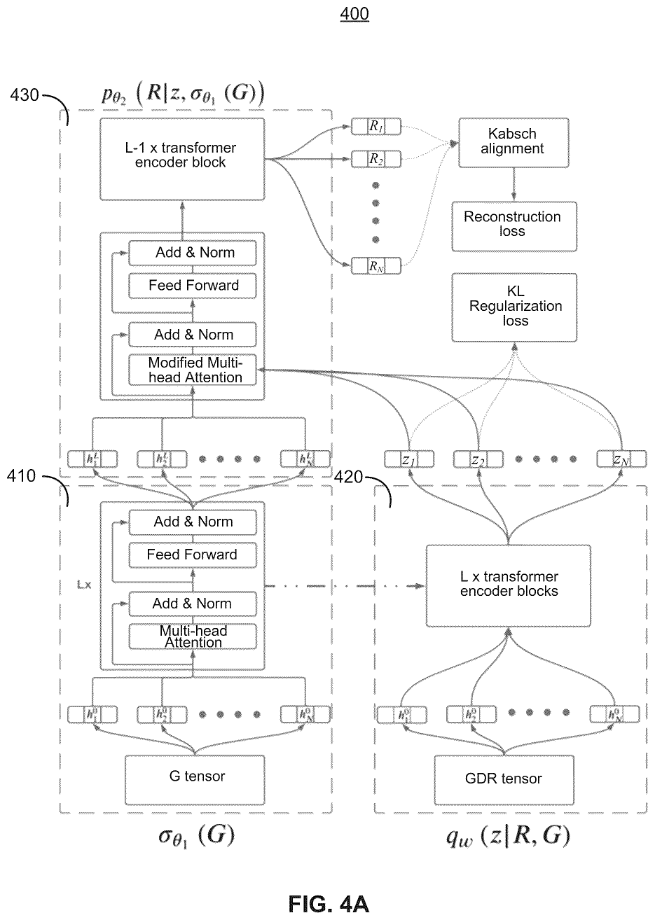

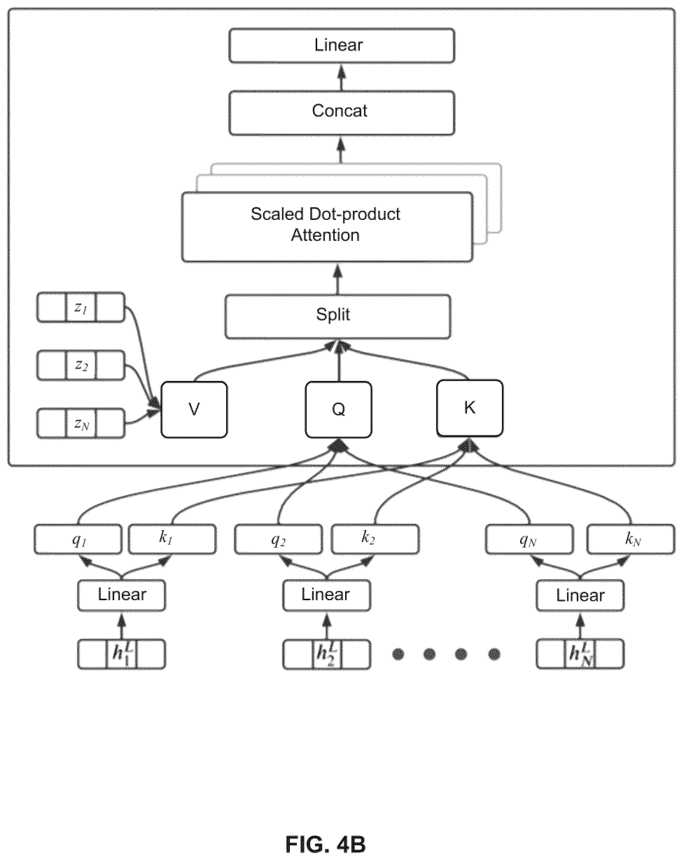

FIG. 4A illustrates an example transformer architecture 400, according to an embodiment. As illustrated, there are two encoders 410 and 420, and one decoder 430. The input for the encoder 410 is the set of vector features generated from the tensor G, while the input for the encoder 420 is the set of vector features generated from the tensor GDR. The outputs from the two encoders 410 and 420 are then input into the encoder 430 to generate 3D conformation.

In some embodiments, there are multiple ways to join together the outputs of the two encoders to form the input to the final decoder. Popular methods include stacking or addition. But neither method can achieve desirable performance. Direct stacking or addition of the sampled output of q_{w} onto the output of σ_{θ}_{₁}, attention weights computed in the first layer of the decoder are easily overwhelmed by the random noise of the sampled values, and become almost indiscernible. This leads to ineffective information aggregation which is then further cascaded through the remaining attention layers. Intuitively, in the first attention layer, the attention weights dictating how much influence an atom exerts on the other should predominantly be determined by the graph structure, and remain stable for the same molecular graph. Further, attention weights are computed by Query (Q) and Key (K) matrices. Therefore, these two matrices should stay stable for the same graph structure. In view of the above, in the disclosed architecture, Query (Q) and Key (K) matrices are computed only from the output of σ_{θ}_{₁} (e.g., {h_{I}^{L}, . . . , h_{N}^{L}}) from the encoder 410, while Value (V) matrices are computed from the output of encoder 420 (e.g., {z₁, . . . , z_{N}}) as illustrated in FIGS. 4A and 4B. The resultant information aggregation is more meaningful and each output vector corresponding to an individual atom carries distinct features, facilitating information aggregation of the ensuing attention layers. A modified multi-head attention layer in the decoder 430 may achieve this and the specific structure for the modified multi-head attention layer is further illustrated in FIG. 4B.

As can be seen from FIG. 4B, Query (indicated by “Q” in FIG. 4B) and Key matrices (indicated by “K” in FIG. 4B) are computed only from the output of e, (e.g., {h_{I}^{L}, . . . , h_{N}^{L}}) from the encoder 410, while Value matrices (indicated by “V” in FIG. 4B) are computed from the output of encoder 420 (e.g., {z₁, . . . , z_{N}}). The remaining structure of the decoder and the two encoders includes certain sublayers implementing a multi-head self-attention mechanism and certain sublayers implementing a fully connected feed-forward network-based linear transformation. As also described earlier, the decoder and the encoders can be first trained before being deployed to implement the described functions.

According to an embodiment, an outcome of using the sliding extended kernel is that the ordering of the generated feature tokens follows the ordering of the atoms. The same permutation order is also preserved through all the transformer components. In addition, following, the single-sample reconstruction loss is formulated as:

$$\begin{matrix}L ( R ) = - log {p}_{θ} ( R \vert z , G ) \\ = - {\sum }_{i = 1}^{N} {\sum }_{j = 1}^{3} {( {R}_{ij} - {A ( \hat{R} , R )}_{ij} )}^{2}\end{matrix} \qquad ( 3 )$$

where A (·) is an alignment function aligning the predicted conformation \hat{R} onto the reference conformation R. The sum aggregation of per atom errors and the permutation preserving property of the feature extraction process make Equation (3) invariant to the permutation of atom order. Furthermore, the Kabsch algorithm is chosen as the alignment method which translates and rotates the predicted conformation onto its corresponding ground-truth before loss computation. This makes the reconstruction loss roto-translation invariant. Finally, the KL-loss component D_{KL} [q_{w}(z|R, G)∥p(z)] does not involve any coordinate. Therefore, the objective function defined in Equation (2) is both permutation and roto-translation invariant, which makes it an ideal model for 3D conformation generation.

In view of the above descriptions, to generate a single conformation during inference, the disclosed molecule conformation generation module 150 first constructs the G tensor of a molecular graph and obtain a single latent sample {z₁, . . . z_{N}} from a standard diagonal Gaussian distribution. The G tensor is passed through the first encoder 410 to produce {h_{I}^{L}, . . . , h_{N}^{L}} which is then combined with the latent sample via the modified multi-head attention mechanism. The output of this modified attention layer further goes through L-1 standard attention layers to be transformed into the final conformation. The entire generation process depends only on a 2D molecular graph, and requires a single sampling step and a single pass of the disclosed transformer architecture, thereby greatly saving the time and computation resources in generating the molecular 3D conformations.

### Example Method

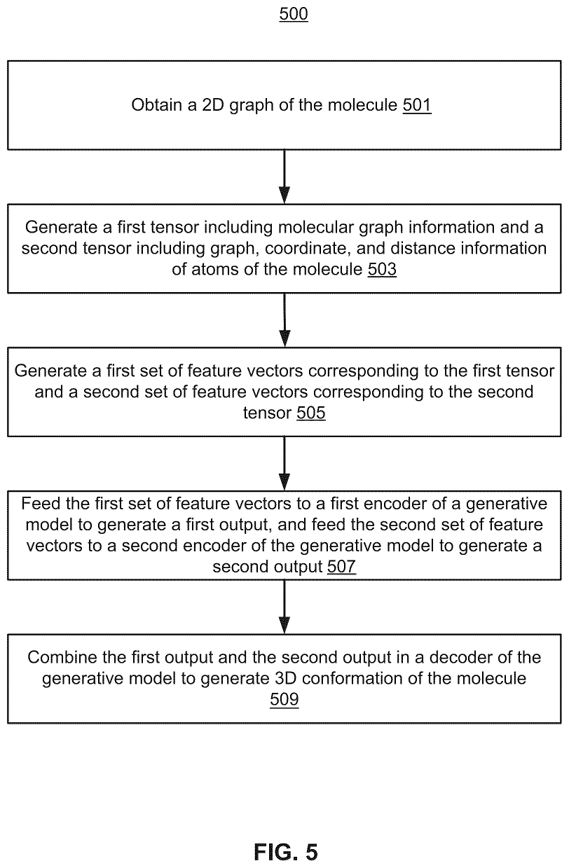

Additionally disclosed herein is an example method 500 for generating a molecular 3D conformation for a molecule, as illustrated in FIG. 5. The method may be implemented by the above-described in-silico drug discovery system. Briefly, in step 501, a 2D molecular graph of a molecule is received. The molecule can have a number of atoms. The 2D molecular graph can be generated by a specific program or application configured for the molecular 2D graph generation. In step 503, a first tensor including graph information and a second tensor including graph, coordinate and distance information are generated based on the molecular 2D graph. The first and second tensors may be generated by a tensor generation module (e.g., tensor generation module 220). The graph information may include certain atom features for each atom and certain bond features for each atom pair. In step 505, a first set of feature vectors corresponding to the first tensor and a second set of feature vectors corresponding to the second tensor are further generated. A specific feature vector generation module (e.g., feature vector generation module 240) may implement the feature vector generation process. In some embodiments, a kernel filter may be employed in a 1D convolution operation in generating the feature vectors. In step 507, the first feature vectors are fed into a first encoder to generate a first output and the second feature vectors are fed into a second encoder to generate a second output. The two encoders may be a part of transformer architecture that additionally includes a decoder. In step 509, the decoder then combines the first output and the second output and directly generates a 3D conformation for the molecule. The decoder may take certain matrices from the first output and other different matrices from the second output in generating the 3D conformation. The entire generation process depends only on a 2D molecular graph and requires a single sampling step and a single pass of the disclosed transformer architecture. In some embodiments, the disclosed method 500 may include additional steps as described earlier.

Non-Transitory Computer Readable Medium

Also provided herein is a computer-readable medium comprising computer executable instructions configured to implement any of the methods described herein. In various embodiments, the computer readable medium is a non-transitory computer readable medium. In some embodiments, the computer readable medium is a part of a computer system (e.g., a memory of a computer system). The computer readable medium can comprise computer executable instructions for implementing a machine learning model for the purposes of predicting a 3D conformation for a molecule.

Computing Device

The methods described above, including the methods of training and deploying machine learning models (e.g., convolutional neural network based encoders), are, in some embodiments, performed on a computing device. Examples of a computing device can include a personal computer, desktop computer laptop, server computer, a computing node within a cluster, message processors, hand-held devices, multi-processor systems, microprocessor-based or programmable consumer electronics, network PCs, minicomputers, mainframe computers, mobile telephones, PDAs, tablets, pagers, routers, switches, and the like.

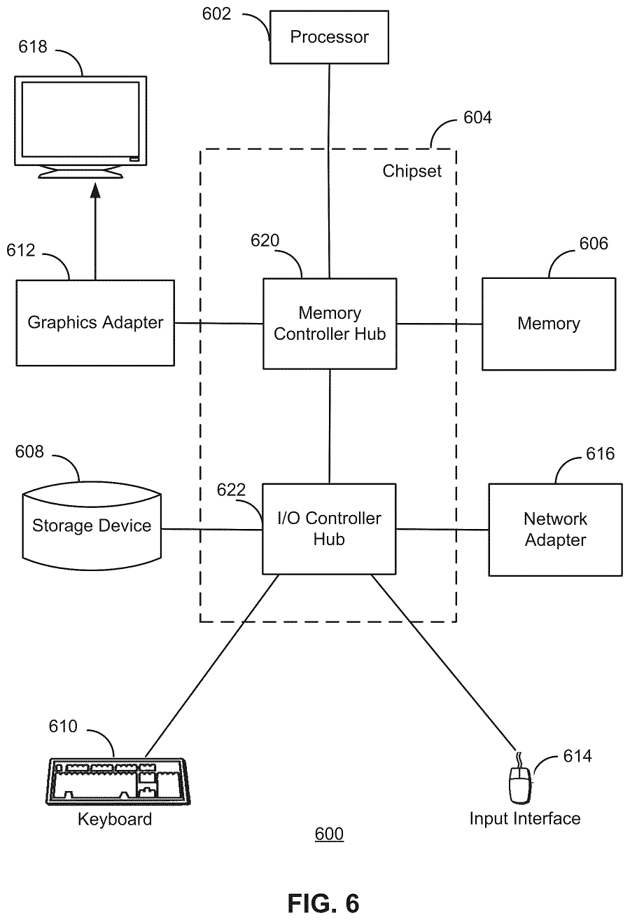

FIG. 6 illustrates an example computing device for implementing systems and methods described above. In some embodiments, the computing device 600 shown in FIG. 6 includes at least one processor 602 coupled to a chipset 604. The chipset 604 includes a memory controller hub 620 and an input/output (I/O) controller hub 622. A memory 606 and a graphics adapter 612 are coupled to the memory controller hub 620, and a display 618 is coupled to the graphics adapter 612. A storage device 608, an input interface 614, and network adapter 616 are coupled to the I/O controller hub 622. Other embodiments of the computing device 600 have different architectures.

The storage device 608 is a non-transitory computer-readable storage medium such as a hard drive, compact disk read-only memory (CD-ROM), DVD, or a solid-state memory device. The memory 606 holds instructions and data used by the processor 602. The input interface 614 is a touch-screen interface, a mouse, track ball, or other type of input interface, a keyboard, or some combinations thereof, and is used to input data into the computing device 600. In some embodiments, the computing device 600 may be configured to receive input (e.g., commands) from the input interface 614 via gestures from the user. The graphics adapter 612 displays images and other information on the display 618. The network adapter 616 couples the computing device 600 to one or more computer networks.

The computing device 600 is adapted to execute computer program modules for providing functionality described herein. As used herein, the term “module” refers to computer program logic used to provide the specified functionality. Thus, a module can be implemented in hardware, firmware, and/or software. In one embodiment, program modules are stored on the storage device 608, loaded into the memory 606, and executed by the processor 602.

The types of computing devices 600 can vary from the embodiments described herein. For example, the computing device 600 can lack some of the components described above, such as graphics adapters 612, input interface 614, and displays 618. In some embodiments, a computing device 600 can include a processor 602 for executing instructions stored on a memory 606.

The methods for generating 3D conformations for molecules can, in various embodiments, be implemented in hardware or software, or a combination of both. In one embodiment, a non-transitory machine-readable storage medium, such as one described above, is provided, the medium comprising a data storage material encoded with machine readable data which, when using a machine programmed with instructions for using said data, is capable of displaying any of the datasets and execution and results of a machine learning model of this invention. Such data can be used for a variety of purposes, such as tensor generation, kernel expansion, feature vector generation, molecular 3D conformation generation, and the like. Embodiments of the methods described above can be implemented in computer programs executing on programmable computers, comprising a processor, a data storage system (including volatile and non-volatile memory and/or storage elements), a graphics adapter, an input interface, a network adapter, at least one input device, and at least one output device. A display is coupled to the graphics adapter. Program code is applied to input data to perform the functions described above and generate output information. The output information is applied to one or more output devices, in known fashion. The computer can be, for example, a personal computer, microcomputer, or workstation of conventional design.

Each program can be implemented in a high level procedural or object oriented programming language to communicate with a computer system. However, the programs can be implemented in assembly or machine language, if desired. In any case, the language can be a compiled or interpreted language. Each such computer program is preferably stored on a storage media or device (e.g., ROM or magnetic diskette) readable by a general or special purpose programmable computer, for configuring and operating the computer when the storage media or device is read by the computer to perform the procedures described herein. The system can also be considered to be implemented as a computer-readable storage medium, configured with a computer program, where the storage medium so configured causes a computer to operate in a specific and predefined manner to perform the functions described herein.

The 2D molecular graphs and molecular 3D conformations generated thereupon can be provided in a variety of media to facilitate their use. “Media” refers to a manufacture that is capable of recording and reproducing the 2D molecular graphs and molecular 3D conformations of the present invention. The 2D molecular graphs and molecular 3D conformations of the present invention can be recorded on computer readable media (e.g., any medium that can be read and accessed directly by a computer). Such media include, but are not limited to: magnetic storage media, such as floppy discs, hard disc storage medium, and magnetic tape; optical storage media such as CD-ROM; electrical storage media such as RAM and ROM; and hybrids of these categories such as magnetic/optical storage media. One of skills in the art can readily appreciate how any of the presently known computer readable mediums can be used to create a manufacture comprising a recording of the present graph and conformation information. “Recorded” refers to a process for storing information on computer readable medium, using any such methods as known in the art. Any convenient data storage structure can be chosen, based on the means used to access the stored information. A variety of data processor programs and formats can be used for storage (e.g., word processing text file, database format, etc.).

### Example Applications

Dataset and Preprocessing

The geometric ensemble of molecules (GEOM) dataset was used for evaluating the performance of the disclosed methods. GEOM contains about 37 million energy and statistical weight annotated molecular conformations corresponding to about 450,000 molecules. This dataset was further divided into two constituent datasets, Drugs and QM9. The Drugs dataset covers about 317,000 median-sized molecules averaging 44.4 number of atoms. The QM9 dataset contains about 133,000 smaller molecules averaging only 18 atoms. 40,000 molecules were randomly selected from each dataset to form a training set. For each molecule, the top 5 most likely conformations were selected. This resulted in about 200,000 training conformations for each train set. For the validation set, 2,500 conformations were randomly selected for both Drugs and QM9 experiments. For testing, 200 molecules were randomly selected, which include more than 50 and less than 500 conformations from the QM9 dataset, and more than 50 and less than 100 conformations from the Drugs dataset.

Determining Input Tensor Graph Size

Basic data analysis was conducted on the entire Drugs dataset to determine the 98.5^{th} percentile of the number of atoms (including hydrogen) to be 69, and the percentage of molecules having more than 69 atoms and with more than 50 and less than 100 conformations is only 0.19%. Accordingly, the size of the input tensor was set to 69×69 for the Drugs dataset. On the other hand, the maximum number of atoms 30 was used for the QM9 dataset. The channel features for the input tensor include atom types, atom charge, atom chirality, bond type, bond stereochemistry and bond in-ring size. For the GDR tensor, 3D coordinate channel and the computed distance channel were further included. The resulting channel depth was 50 for the GDR tensor and 46 for the G tensor.

Implementation Details

The proposed generative model was implemented using Tensorflow 2.3.1. Specifically, tensor graphs of molecules were generated in accordance with FIG. 3A, feature vectors were generated using N×3 kernels in accordance with FIG. 3B, and the feature vectors were analyzed using the transformer architecture shown in FIGS. 4A and 4B. All three transformer encoders/decoder of the disclosed conditional AutoEncoder framework follow the standard Tensorflow implementation in https://www.tensorflow.org/text/tutorials/transformer. All of the encoders/decoder had 4 layers, 8 heads and a latent dimension of 256. However, the latent dimension was increased to 512 for the point-wise feed forward network. Both QM9 and Drugs experiments shared the same network architecture and training hyper-parameter configuration. Training was conducted on a single Tesla V100 GPU. To tackle the notorious issue of KL vanishing, KL weight was set to a minimum of 1e⁻⁴ and doubled every 70,000 iterations until a maximum weight of 0.0256 was reached. For both datasets, some neural networks were trained for 500,000 iterations with a batch size of 128. Additionally, other neural networks were trained on the Drugs dataset for 30 epochs with a constant learning rate of 1e⁻⁴ and batch size of 32.

Evaluation Metrics.

Widely accepted coverage score (COV) and matching score (MAT) were used to evaluate the performance of the proposed generative model. These two scores were computed as:

$$C O V ( {C}_{g} - {C}_{r} ) = \frac{1}{\vert {C}_{r} \vert} \vert \{ R ∈ {C}_{r} \vert R M S D ( R , \hat{R} ) \leq δ , ∀ \hat{R} ∈ {C}_{g} \} \vert \qquad ( 4 )$$

$$M A T ( {C}_{g} - {C}_{r} ) = \frac{1}{\vert {C}_{r} \vert} {\sum }_{R ∈ {C}_{r}} min R M S D ( R , \hat{R} ) \qquad ( 5 )$$

where C_{g} is the set of generated conformations and Cᵣ is the corresponding reference set. The size of C_{g} is twice that of Cᵣ, and for every molecule, twice the number of conformations were generated at that of reference conformations. δ is a predefined threshold and is set to 0.5 Å for QM9 and 1.25 Å for Drugs respectively. RMSD stands for the root-mean-square deviation between R and R. While the COV score measures the ability of a model in generating diverse conformations to cover all reference conformations, the MAT score measures how well the generated conformations match the ground-truth. A good generative model should have a high COV score and a low MAT score.

Results and Discussion

The performance of the disclosed generative model (or disclosed method) was evaluated by comparing it to 13 other existing methods. Specifically, the COV and MAT scores were determined by using the same test data generation configuration. Among the total 14 methods, six are distance-based methods, three are reconstruction-based methods, four are direct methods (including the disclosed method), and one is a classical method.

Distance-based methods, except for Method 7 and Method 9, had relatively poor performance when compared to that of the classic Method 1. Superior performance of Method 1 may be due to the application of an additional empirical force field (FF) to optimize the generated structure. To compare, the disclosed method was performed with FF optimization, which was shown to outperform the other methods by a significant margin, as shown in Table 2.

TABLE 2
Performance comparison between methods with FF optimization

| | COV(↑, %) | | MAT(↓, Å) | | |
|---|---|---|---|---|---|
| | Mean | Median | Mean | Median | Type |
| Method 2 + FF[10] | 83.08 | 95.21 | 0.9829 | 0.9177 | Direct |
| Method 3 + FF[10] | 84.68 | 93.94 | 0.9129 | 0.9090 | Distance |
| Method 5 + FF[10] | 92.28 | 98.15 | 0.7740 | 0.7338 | Distance |
| Method 6 + FF[10] | 91.88 | 100.00 | 0.7634 | 0.7312 | Distance |
| Method 10 + FF[13] | 92.27 | 100.00 | 0.7618 | 0.7340 | Recon* |
| Disclosed Method + FF | 95.36 (0.34) | 100 (0) | 0.6814 (0.0023) | 0.6605 (0.0064) | Direct |

Note:
“Recon” represents “Reconstruction” or a reconstruction-based method.

The application of FF further introduced complexity to the already complex two-stage generative model. Method 7 attempted to rectify this weakness by simulating a pseudo gradient-based force field. It was observed that inter atomic distances are continuously differential with respect to atomic coordinates, and the gradient fields of these two can be connected by the chain rule. Such a force field can be utilized in the annealed Langevin dynamics sampling to sequentially guide atom positions to a valid conformation. Method 9 further improves the performance of Method 7 by using a dynamically constructed graph structure that is able to model long range atom interaction. Despite being posed as a direct method, during inference, both Method 7 and Method 9 still need to compute atom distance as an intermediate step. Noticeably, Method 9 also requires dynamically changing the graph structure for every sampling step. As shown in Table 3, Method 7 and Method 9 outperform classical Method 1 by a significant margin in both QM9 and Drugs experiments. Nevertheless, their main weakness lies in the fact they require numerous Langevin dynamics sampling steps to attain desirable performance. For example, it takes Method 7 approximately 8500 seconds to fully decode 200 QM9 molecules and a staggering 11500 seconds for decoding 200 Drugs molecules.

TABLE 3
Performance comparison between the disclosed method
and 13 other methods on GEOM QM9 and Drugs datasets:

| | QM9 | | | | Drugs | | | | |
|---|---|---|---|---|---|---|---|---|---|
| | COV(↑, %) | | MAT(↓, Å) | | COV(↑, %) | | MAT(↓, Å) | | |
| Method | Mean | Median | Mean | Median | Mean | Median | Mean | Median | Type |
| Method 1 | 82.26 | 90.78 | 0.3447 | 0.2935 | 60.91 | 65.70 | 1.2026 | 1.1252 | Classic |
| Method 2 | 0.09 | 0.00 | 1.6713 | 1.6088 | 0.00 | 0.00 | 3.0702 | 2.9937 | Direct |
| Method 3 | 73.33 | 84.21 | 0.4245 | 0.3973 | 8.27 | 0.00 | 1.9722 | 1.9845 | Dist* |
| Method 4 | NA | NA | NA | NA | 51.94 | 51.58 | 1.3822 | 1.3231 | Dist* |
| Method 5 | 78.05 | 82.48 | 0.4219 | 0.3900 | 53.96 | 57.06 | 1.2487 | 1.2247 | Dist* |
| Method 6 | 77.98 | 82.82 | 0.3778 | 0.3770 | 55.20 | 59.43 | 1.2487 | 1.2247 | Dist* |
| Method 7 | 88.49 | 94.13 | 0.2673 | 0.2685 | 62.15 | 70.93 | 1.1629 | 1.1596 | Dist* |
| Method 8 | 71.26 | 72.00 | 0.3731 | 0.3731 | 67.16 | 71.71 | 1.0875 | 1.0586 | Direct |
| Method 9 | 91.49 | 95.92 | 0.2139 | 0.2137 | 78.73 | 94.39 | 1.0154 | 0.9980 | Dist* |
| Method 10 | 90.54 | 94.61 | 0.2104 | 0.2021 | 89.13 | 97.88 | 0.8629 | 0.8529 | Recon* |
| Method 11 | 97.95 | 100 | 0.1831 | 0.1695 | 91.91 | 100 | 0.7863 | 0.7794 | Recon* |
| Method 12 | NA | NA | NA | NA | 77.78 | 86.09 | 1.0657 | 1.0563 | Direct |
| Method 13 | 96.98 | 98.47 | 0.2365 | 0.2312 | 91.27 | 100 | 0.8287 | 0.7908 | Direct |
| Disclosed | 98.34 | 100 | 0.2195 | 0.2174 | 92.86 | 100 | 0.8478 | 0.8206 | Direct |
| Method | (0.1700) | (0) | (0.0015) | (0.0038) | (0.2300) | (0) | (0.0020) | (0.0056) | |

Note:
“Recon” represents “Reconstruction” or a reconstruction-based method, and “Dist” represents “Distance” or a distance-based method.

One of the main goals of Method 10 is to be completely free of the dependence on atom distance. To achieve this, transformations are directly applied to 3D conformation, through which, a random or distorted conformation can be sequentially denoised to a valid conformation. Such a transformation preserves rotation and translation. This necessitates the design of a sophisticated SE(3)-equivariant transition kernel. In spite of its claim of not involving computing distance as an intermediate step, the equivariant graph field network adopted in Method 10 still relies on a distance-like quantity ∥xᵢ^{L}−xⱼ^{L}∥² for every step of transformation.

Method 10 produces promising performance on both Drugs and QM9 datasets, significantly widening the gap between distance-based methods and reconstruction-based methods. Unfortunately, like its predecessor Method 9, during inference time, numerous diffusion steps are implemented, requiring approximately the same amount of time for decoding QM9 and Drugs testing datasets. Method 11 circumvents the sampling step by reformulating the molecular generation problem as an optimization problem. A properly optimized generative model can push randomly sampled conformations to valid ones in a single pass of the model. The structure of Method 11 requires maintaining a pair interaction matrix (N×N) through every attention layer. In addition, Method 11 has a significantly larger transformer structure as compared to the disclosed model, featuring 15 attention layers, 64 attention heads and a latent dimension size of 2048. The Method 11 model is also first pre-trained on a much larger dataset, and then fine-tuned on the GEOM dataset for conformation generation. The trained model generates a good performance on both Drugs and QM9 datasets. Despite using a much smaller transformer model, the disclosed model offers competitive performance as compared to Method 11, yielding a slightly better COV score for the Drugs dataset.

Method 2 is one of the first methods to generate molecular conformation directly from a 2D molecular graph. However, it yielded a COV score of 0, indicating its incapability of generating any meaningful 3D conformation for the Drugs dataset. The reason could be attributed to the use of a vanilla graph neural network that is inferior to other more advanced adaptions, and a simple loss function that computes root-mean-square deviation directly from predicted coordinates. Method 12 attempted to revitalize the same framework by adapting a more advanced graph neural network structure. Another major modification adopted in Method 12 is including symmetric permutation invariance to the loss function. This is fundamentally different from permutation order invariance, where changing atom ordering does not affect the value of the loss function as atom coordinates are permuted together. The symmetric invariance goes a step further. That is, swapping the coordinates of the symmetric substructure with atom ordering fixed should yield the same root-mean-square deviation value. However, this involves enumerating all possible permutations which can become very expensive for large molecules. Method 12 outperformed Method 11 on COV scores; nevertheless, its variant using the same loss function as the disclosed model performed significantly worse on both Drugs and QM9 datasets. This indicates that the disclosed model has better feature extraction capability, eliminating the need for a more complex loss function for achieving comparable performance.

In summary, extensive experiments on the GEOM dataset have demonstrated the following three main advantages of the disclosed model. (1) The disclosed model is a direct generative model. The disclosed model does not involve any distance computation or numerous sampling steps at inference time. It generates conformation directly from a 2D molecular graph in a single sampling step. As compared to other distance- or reconstruction-based methods, it takes only 62 seconds using a single Xeon 8163 CPU core4 to decode 200 QM9 molecules and 128 seconds for 200 Drugs molecules; which is a 100× speed up in terms of efficiency. (2) The disclosed model does not require any sophisticated adaption of graph neural network for feature extraction nor necessitates the design of any complex SE(3)-equivariant coordinate transformation. (3) Its simple yet intuitive feature engineering enables complete information aggregation at the input feature level, making it possible to use an off-the-shelf transformer encoder and simple loss function to achieve competitive conformation generation capability against other existing well-performed methods. These three advantages translate directly to the excellent practicality of the disclosed method.

Altogether, disclosed herein is a neural network-based molecular 3D conformation generation algorithm. The presented algorithm is simple, easy to implement, and demonstrates excellent conformation generation capacity. Its competitive performance has been demonstrated by comparison to a number of recently published state-of-the-art methods on 3D conformation generation.

### REFERENCES

1. Hongming Chen, Ola Engkvist, Yinhai Wang, Marcus Olivecrona, and Thomas Blaschke. The rise of deep learning in drug discovery. Drug discovery today, 23(6):1241-1250, 2018.
2. Shion Honda, Hirotaka Akita, Katsuhiko Ishiguro, Toshiki Nakanishi, and Kenta Oono. Graph residual flow for molecular graph generation. arXiv preprint arXiv:1909.13521, 2019.
3. Omar Mahmood, Elman Mansimov, Richard Bonneau, and Kyunghyun Cho. Masked graph modeling for molecule generation. Nature communications, 12(1):1-12, 2021.
4. Hongyang K Yu and Hongjiang C Yu. Powerful molecule generation with simple convnet. Bioinformatics, 38(13):3438-3443, 2022.
5. Xiaoxue Wang, Yujie Qian, Hanyu Gao, Connor W Coley, Yiming Mo, Regina Barzilay, and Klavs F Jensen. Towards efficient discovery of green synthetic pathways with monte carlo tree search and reinforcement learning. Chemical science, 11(40):10959-10972, 2020.
6. Paul C D Hawkins. Conformation generation: the state of the art. Journal of chemical information and modeling, 57(8):1747-1756, 2017.
7. Aayush Gupta and Huan-Xiang Zhou. Machine learning-enabled pipeline for large-scale virtual drug screening. Journal of Chemical Information and Modeling, 61(9):4236-4244, 2021.
8. Gregor N C Simm and José Miguel Hernández-Lobato. A generative model for molecular distance geometry. arXiv preprint arXiv:1909.11459, 2019.
9. Minkai Xu, Shitong Luo, Yoshua Bengio, Jian Peng, and Jian Tang. Learning neural generative dynamics for molecular conformation generation. arXiv preprint arXiv:2102.10240, 2021.
10. Minkai Xu, Wujie Wang, Shitong Luo, Chence Shi, Yoshua Bengio, Rafael Gomez-Bombarelli, and Jian Tang. An end-to-end framework for molecular conformation generation via bilevel programming. In International Conference on Machine Learning, pages 11537-11547. PMLR, 2021.
11. Chence Shi, Shitong Luo, Minkai Xu, and Jian Tang. Learning gradient fields for molecular conformation generation. In International Conference on Machine Learning, pages 9558-9568. PMLR, 2021.
12. Shitong Luo, Chence Shi, Minkai Xu, and Jian Tang. Predicting molecular conformation via dynamic graph score matching. Advances in Neural Information Processing Systems, 34:19784-19795, 2021.
13. Minkai Xu, Lantao Yu, Yang Song, Chence Shi, Stefano Ermon, and Jian Tang. Geodiff: A geometric diffusion model for molecular conformation generation. arXiv preprint arXiv:2203.02923, 2022.
14. Gengmo Zhou, Zhifeng Gao, Qiankun Ding, Hang Zheng, Hongteng Xu, Zhewei Wei, Linfeng Zhang, and Guolin Ke. Uni-mol: A universal 3d molecular representation learning framework. 2022.
15. Ashish Vaswani, Noam Shazeer, Niki Parmar, Jakob Uszkoreit, Llion Jones, Aidan N Gomez, Łukasz Kaiser, and Illia Polosukhin. Attention is all you need. Advances in neural information processing systems, 30, 2017.
16. John Jumper, Richard Evans, Alexander Pritzel, Tim Green, Michael Figurnov, Olaf Ronneberger, Kathryn Tunyasuvunakool, Russ Bates, Augustin Žídek, Anna Potapenko, et al. Highly accurate protein structure prediction with alphafold. Nature, 596(7873):583-589, 2021.
17. Victor Garcia Satorras, Emiel Hoogeboom, and Max Welling. E (n) equivariant graph neural networks. In International conference on machine learning, pages 9323-9332. PMLR, 2021.
18. Elman Mansimov, Omar Mahmood, Seokho Kang, and Kyunghyun Cho. Molecular geometry prediction using a deep generative graph neural network. Scientific reports, 9(1):1-13, 2019.
19. Jinhua Zhu, Yingce Xia, Chang Liu, Lijun Wu, Shufang Xie, Tong Wang, Yusong Wang, Wengang Zhou, Tao Qin, Houqiang Li, et al. Direct molecular conformation generation. arXiv preprint arXiv:2202.01356, 2022.
20. Justin Gilmer, Samuel S Schoenholz, Patrick F Riley, Oriol Vinyals, and George E Dahl. Neural message passing for quantum chemistry. In International conference on machine learning, pages 1263-1272. PMLR, 2017.
21. Olaf Ronneberger, Philipp Fischer, and Thomas Brox. U-net: Convolutional networks for biomedical image segmentation. In International Conference on Medical image computing and computer-assisted intervention, pages 234-241. Springer, 2015.
22. Diederik P Kingma and Max Welling. Auto-encoding variational bayes. arXiv preprint arXiv:1312.6114, 2013.
23. Simon Axelrod and Rafael Gómez-Bombarelli. Geom, energy-annotated molecular conformations for property prediction and molecular generation. Scientific Data, 9(1):185, 2022.
24. Hao Fu, Chunyuan Li, Xiaodong Liu, Jianfeng Gao, Ash Celikyilmaz, and Lawrence Carin. Cyclical annealing schedule: A simple approach to mitigating kl vanishing. arXiv preprint arXiv:1903.10145, 2019.
25. Sereina Riniker and Gregory A Landrum. Better informed distance geometry: using what we know to improve conformation generation. Journal of chemical information and modeling, 55(12):2562-2574, 2015.
26. Thomas A Halgren. Merck molecular force field. v. extension of mmff94 using experimental data, additional computational data, and empirical rules. Journal of Computational Chemistry, 17(5-6):616-641, 1996.
27. Shaked Brody, Uri Alon, and Eran Yahav. How attentive are graph attention networks? arXiv preprint arXiv:2105.14491, 2021.
28. Peter W Battaglia, Jessica B Hamrick, Victor Bapst, Alvaro Sanchez-Gonzalez, Vinicius Zambaldi, Mateusz Malinowski, Andrea Tacchetti, David Raposo, Adam Santoro, Ryan Faulkner, et al. Relational inductive biases, deep learning, and graph networks. arXiv preprint arXiv:1806.01261, 2018.

What is claimed is:

1. A method for generating a three-dimensional (3D) conformation of a molecule, the method comprising:
obtaining a two-dimensional (2D) graph of the molecule;
generating a first tensor comprising molecular graph information and a second tensor comprising graph, coordinate, and distance information of atoms of the molecule;
generating a first set of feature vectors corresponding to the first tensor and a second set of feature vectors corresponding to the second tensor;
feeding the first set of feature vectors to a first encoder of a generative model to generate a first output, and feeding the second set of feature vectors to a second encoder of the generative model to generate a second output; and
combining the first output and the second output in a decoder of the generative model to generate the 3D conformation of the molecule.

2. The method of claim 1, wherein generating the first tensor comprises adding an additional dimension to an adjacency matrix including one or more atom features for the atoms of the molecule and one or more bond features for bonds, corresponding to atom pairs, included in the molecule.

3. The method of claim 2, wherein a diagonal section of the first tensor holds the one or more atom features for the atoms of molecule, and off-diagonal sections of the first tensor hold the one or more bond features for the bonds included in the molecule.

4. The method of claim 2, wherein the one or more atom features for an atom included in the molecule comprise one or more of an atom type, atom charge, or atom chirality for the atom.

5. The method of claim 2, wherein the one or more bond features for a bond included in the molecule comprise one or more of a bond type, a bond stereochemistry type, an associated ring size, or a normalized bond length for the bond.

6. The method of claim 5, wherein the bond type comprises a virtual bond.

7. The method of claim 6, wherein the first tensor represents a fully connected symmetric tensor in which virtual bonds are extended across all atoms of the molecule.

8. The method of claim 2, wherein generating the first set of feature vectors comprises generating a set of atom feature vectors for the atoms of the molecule and a set of bond feature vectors for the bonds included in the molecule.

9. The method of claim 8, wherein an atom feature vector for an atom is generated by stacking the one or more atom features for the atom included in the molecule, wherein each of the one or more atom features for the atom is one-hot encoded.

10. The method of claim 8, wherein a bond feature vector for a bond is generated by:
summing atom feature vectors for a pair of atoms associated with the bond to generate a new vector; and
stacking the new vector with one-hot encoded bond type vector, normalized bond length, and one-hot encoded ring size vector associated with the bond.

11. The method of claim 8, wherein generating the second tensor comprises adding a coordinate channel to a respective atom feature vector and adding a Euclidean distance channel to a respective bond feature vector.

12. The method of claim 1, wherein generating the first set of feature vectors comprises encoding the first tensor using a one-dimensional (1D) convolution operation, and generating the second set of feature vectors comprises encoding the second tensor using the 1D convolution operation.

13. The method of claim 12, wherein using the 1D convolution operation comprises adjusting a kernel height or width of a kernel to equal a height or width of the first tensor or the second tensor during the 1D convolution operation.

14. The method of claim 13, wherein the kernel height or width of the first tensor or the second tensor remains unchanged and equals a kernel size of the kernel during the 1D convolution operation.

15. The method of claim 14, wherein the kernel size of the kernel after adjusting the kernel length is N×3 kernel or N×4 kernel, wherein N is the length of the first tensor or the second tensor.

16. The method of claim 1, wherein combining the first output and the second output in the decoder of the generative model to generate the 3D conformation of the molecule comprises: computing, in a first multi-head attention layer of the decoder, query and key matrices based on the first output.

17. The method of claim 1, wherein combining the first output and the second output in the decoder of the generative model to generate the 3D conformation of the molecule comprises: reparametrizing the second output to generate value matrices for a first multi-head attention layer of the decoder.

18. The method of claim 1, wherein the first encoder, the second encoder, and the decoder included in the generative model are arranged in a conditional variational autoencoder framework.

19. The method of claim 1, wherein the generative model comprises a convolutional neural network.

20. A non-transitory computer readable medium comprising instructions that, when executed by a processor, cause the processor to:
obtain a two-dimensional (2D) graph of a molecule;
generating a first tensor comprising molecular graph information and a second tensor comprising graph, coordinate, and distance information of atoms of the molecule;
generating a first set of feature vectors corresponding to the first tensor and a second set of feature vectors corresponding to the second tensor;
feeding the first set of feature vectors to a first encoder of a generative model to generate a first output, and feeding the second set of feature vectors to a second encoder of the generative model to generate a second output; and
combining the first output and the second output in a decoder of the generative model to generate a three-dimensional (3D) conformation of the molecule
